(19) United States
(12) Patent Application Publication
(10) Pub. No.: US 2009/0268776 A1
(43) Pub. Date: Oct. 29, 2009

(54) Piezoelectric Resonator and Temperature Sensor

(76) Inventor: Mitsuaki Koyama, Saitama (JP)

Correspondence Address: JORDAN AND HAMBURG LLP, 122 EAST 42ND STREET, SUITE 4000, NEW YORK, NY, 10168, US

(21) Appl. No.: 11/989,127

(22) PCT Filed: Jul. 21, 2006
(86) PCT No.: PCT/JP2006/314940

§ 371 Date: Mar. 10, 2008

(51) Int. Cl. G01K 11/26; H01L 41/047

(52) U.S. Cl. 374/119; 310/364; 374/E11.011

(57) ABSTRACT

An object of the present invention is to provide a piezoelectric resonator provided with a electrode on the surface of a plate piezoelectric blank, which excites the piezoelectric blank, the piezoelectric resonator being capable of suppressing deterioration of an electrode under high temperature circumstances. Another object is to provide a temperature sensor suitable for temperature measurement at high temperatures.

As a concrete means for solving the problems is that the electrode includes a first metal layer, formed on the surface of the piezoelectric blank, and made of at least one kind selected from the group consisting of chromium (Cr), titanium (Ti), nickel (Ni), aluminum (Al) and copper (Cu), or having the same adhesion to the above-described piezoelectric blank as that of these metals; a second metal layer made of gold (Au) or silver (Ag) deposited on the surface of the first metal layer; and a third metal layer made of chromium (Cr) deposited on the surface of the second metal layer. The temperature sensor using the piezoelectric resonator is capable of measuring temperature even at high temperatures including 300° C. or above with high reliability.

### TECHNICAL FIELD

The present invention relates to a piezoelectric resonator, more in detail, the piezoelectric resonator prepared by stacking a plenty of various metals as a electrode which is formed on the surface of a plate piezoelectric blank, and a temperature sensor using the piezoelectric resonator.

### BACKGROUND ART

Conventionally, a thermocouple has been used as the temperature sensor. Although the range of temperature measurement by the temperature sensor using the thermocouple is wide, the heat capacity is low, which results in low responsively in temperature measurement for the object to be measured. In recent years, however, a piezoelectric resonator such as a quartz crystal resonator has been used as a temperature sensor because of its high responsively when conducting temperature measurement for the object to be measured. The oscillation frequency of a quartz crystal resonator varies according to the temperature variation. Temperature measurements are carried out by detecting the temperature change as a variation in oscillation frequency.

The structure of the quartz crystal resonator used as a temperature sensor in this manner will be explained briefly. The quartz crystal resonator is provided with a electrode formed on the surface of a plate quartz piece for exciting the quartz piece. The electrode is made of a metal such as chromium (Cr) or the like for instance and is deposited on the surface of the quartz piece by sputtering. Chromium is generally used for the electrode material due to the ease with which it is adsorbed onto the surface of a quartz piece. However, due to its large electric resistance, material of excellent adhesion to chromium such as gold (Au) or the like is deposited on the surface of chromium so as to lower the electric resistance of the whole electrode. In other words, an electrode formed on the surface of the quartz piece in this example has a structure composed of two layers, a chromium (Cr) layer and a gold (Au) layer.

The temperature measurement range of the temperature sensor using a quartz crystal resonator configured in this fashion is, however, limited to about 300° C., and means capable of measuring a temperature in a further higher temperature range with high reliability is demanded. That is, at a temperature of 300° C. or above, gold (Au) atoms are scattered from the gold (Au) surface to make the whole electrode thinner in the above-described electrode, which makes it impossible to oscillate the quartz crystal efficiently, so that the impedance is increased and the resonant frequency of the quartz crystal resonator becomes larger than the theoretical value. This causes the problem of increasing error in the temperature measurement. It is considered that the reason of scattering gold (Au) from the electrode in this manner is not because of its thermal distortion but because of activated energy.

Patent Document 1 described that by depositing chromium (Cr), gold (Au) and silver (Ag) in this order as the electrode formed on the surface of a quartz substrate, the adhesion of the quartz substrate to the electrode and those between the respective metals can be enhanced, but the silver (Ag) formed on the surface of the gold (Au) is poorer in heat resistance than the gold (Au), so that silver (Ag) atoms scatter around from the surface of the silver (Ag) at about 180° C., which makes the whole electrode thinner. Accordingly, there is the same problem as described above when the above-described quartz crystal resonator is used as a temperature sensor.

Patent Document 2 describes a quartz crystal resonator prepared by depositing chromium (Cr), chromium (Cr) and gold (Au) in this order as an electrode formed on the surface of the quartz substrate. Since the outermost layer of the above-described electrode is gold (Au), it is considered that the same problem as described above may occur when such a quartz crystal resonator is used as a temperature sensor.

### Patent Document 1

Japanese Patent Laid-open No. 2002-344278 (claim 1, paragraph 0016)

### Patent Document 2

Japanese Patent Laid-open No. 2000-223993 (claim 1, paragraphs 0009 and 0011)

### DISCLOSURE OF THE INVENTION

The present invention has been made in view of the above circumstances, and an object of the present invention is to provide a piezoelectric resonator capable of suppressing deterioration of an electrode under high temperature circumstances. Another object of the present invention is to provide a temperature sensor suitable for temperature measurement at high temperatures.

The present invention is characterized by that a piezoelectric resonator provided with a electrode on the surface of the plate piezoelectric blank, which excites the piezoelectric blank, in which the above-described electrode includes:

a first metal layer, formed on the surface of the piezoelectric blank, and made of at least one kind selected from the group consisting of chromium (Cr), titanium (Ti), nickel (Ni), aluminum (Al) and copper (Cu), or having the same adhesion to the above-described piezoelectric blank as that of these metals;

a second metal layer made of gold (Au) or silver (Ag) deposited on the surface of the first metal layer; and

a third metal layer made of chromium (Cr) deposited on the surface of the second metal layer.

The thickness of the third metal layer of the electrode in the above-described piezoelectric resonator is preferably 0.05 nm to 0.1 nm for instance.

A temperature sensor of the present invention including a piezoelectric resonator and an oscillation circuit, and measuring temperatures by detecting the change in frequency oscillated from the oscillation circuit uses the above-described piezoelectric resonator. The temperature measurement range of the temperature sensor includes 300° C. and above for instance.

The electrode of the present invention formed on the surface of a plate piezoelectric blank, for instance, a quartz piece is prepared by depositing chromium (Cr) on gold (Au) or silver (Ag). Accordingly, chromium (Cr) and gold (Au) or silver (Ag) enter between mutual molecules to make a state close to a solid solution, which results in a state that the gold (Au) atoms or the silver (Ag) atoms are resistant to be scattered around from the surface of the electrode even at a high temperature. Furthermore, since metal such as chromium (Cr) or the like which has good adhesion to the piezoelectric blank is used for a base plate material, a piezoelectric resonator excellent in heat resistance and adhesion can be obtained. Accordingly, when a temperature sensor is formed with this piezoelectric resonator, it is possible to conduct temperature measurement with high accuracy even at high temperatures such as 300° C. or more for instance, for which actual measurement could not have been successfully conducted conventionally, so that a very useful temperature sensor substituting for the slow-response thermocouple.

### BRIEF DESCRIPTION OF DRAWINGS

FIG. 1 is a schematic plan view showing a lead insertion type quartz crystal resonator relating to an embodiment of the present invention;

FIG. 2 is a schematic sectional view of the above-described quartz crystal resonator;

FIGS. 3A and 3B are imaginary views showing the appearance of the electrode formed on the surface of the quartz piece;

FIG. 4 is a block diagram showing an example of the temperature sensors using the above-described quartz crystal resonator;

FIG. 5 is a characteristic diagram showing the result of an experimental example conducted for the purpose of confirming the effect of the present invention; and

FIG. 6 is a characteristic diagram showing the result of an experimental example conducted for the purpose of confirming the effect of the present invention.

### BEST MODE FOR CARRYING OUT THE INVENTION

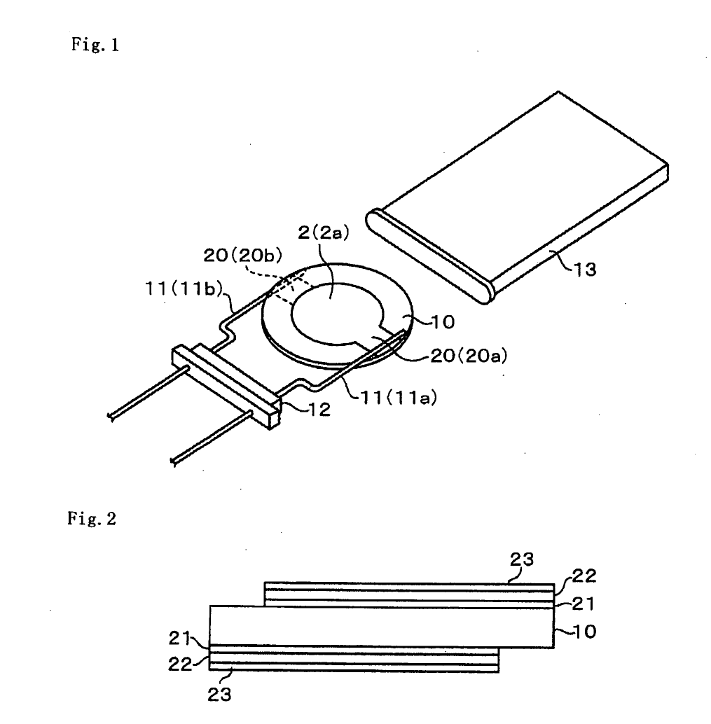

FIG. 1 is a view showing an embodiment when a piezoelectric resonator of the present invention is applied to a lead insertion type quartz crystal resonator. An Arabic numeral 10 in FIG. 10 is a circular plate quartz piece having the equivalent thickness of 1 μm to 300 μM for instance, preferably, 185 mm, and electrodes 2 (2a and 2b) for exciting the quartz piece 10 are formed on both surfaces of the quartz piece 10. Thin film extracting electrodes 20 (20a and 20b) are respectively connected to one drive electrode 2a and the other drive electrode 2b. U-shaped supporter members 11 (11a and 11b) are connected to one extracting electrode 20a and the other extracting electrode 20b, and the supporter members 11 (11a and 11b) horizontally extend to the quartz piece 10 in a band shape via a supporter holding member 12. The supporter members 11 (11a and 11b) are composed of lead lines made of copper for instance. 13 in FIG. 1 is a protection lid (cover) 13 for shielding the quartz piece 10, and the supporter holding member 12 fits exactly into an opening of the protection lid 13.

As shown in FIG. 2, the electrodes 2 (2a and 2b) and 20 (20a and 20b) formed on both sides of the quartz piece 10 are prepared by depositing a chromium (Cr) layer 21 being the first metal layer, a gold (Au) layer 22 being the second metal layer and a chromium (Cr) layer 23 being the third metal layer in this order. The chromium layer 21 is familiar with the quartz piece 10 and has high adhesion, which makes the chromium layer 21 serve as an adhesive layer to the quartz piece 10. The preferable magnitude of the film thickness of the chromium layer 21 is considered to be 1 nm to 10 nm for instance. The reason of determining the thickness to be such a magnitude is because if it is less than 1 nm, exfoliation of the electrode may occur, and if it is thicker than 10 nm, serial resistance may increase. It should be noted that the first metal layer is not limited to chromium (Cr) provided that it can secure adhesion, and metals selected from the group consisting of titanium (Ti), nickel (Ni), aluminum (Al) and copper (Cu) or a metal having adhesion to the quartz piece 10 in a similar degree to these metals can be used for instance.

Since the gold (Au) layer 22 has an affinity for the lower chromium layer 21, it is formed having high adhesion with the chromium layer 21. The gold (Au) layer 22 serves the purpose of lowering the electric resistance of the whole electrode 2. The thickness of the gold (Au) layer 22 is determined to be between 80 nm to 200 nm for instance. The reason for determination of the film thickness at this thickness is that if it is thinner than 80 nm, the serial resistance may increase, and if it is thicker than 200 nm, the oscillation frequency may jump.

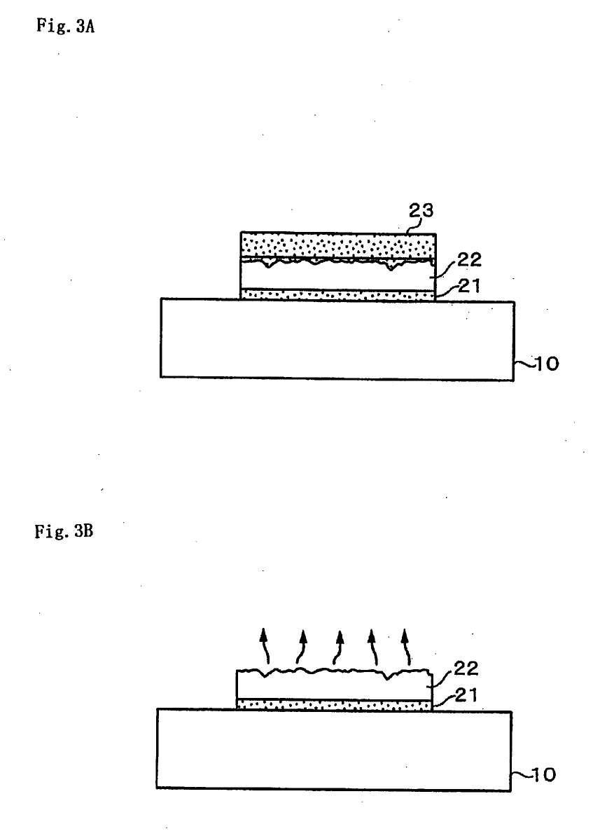

In addition, the chromium (Cr) layer 23, the third metal layer, is formed to serve the function of reducing scattering of gold (Au) atoms from the surface of the electrode 2 in cooperation with the gold (Au) layer 22, the second metal layer, even at a high temperature, for instance, at 300° C. or above. When the thin chromium (Cr) layer 23 is formed on the surface of the gold (Au) layer 22 as shown in the imaginary view in FIG. 3A, molecules in the other layer 23 (22) enter into molecules in the one layer 22 (23), which results in formation of a layer close to a solid solution of gold (Au) and chromium (Cr) on the upper layer of the electrode 2 so that the activation energy level for scattering the gold (Au) atoms is higher. Thus, the gold atoms become resistant to be scattered even at high temperatures. If there is no formation of the chromium (Cr) layer 23 on the surface of the gold (Au) layer 22, scattering of gold (Au) atoms from the surface of the gold (Au) layer 22 may be activated at high temperatures, for instance, at 300° C. or above, as shown in the imaginary view of FIG. 3B. Note that the preferable film thickness of the chromium (Cr) layer 23, the third metal layer will be described in detail in an embodiment to be described later. In addition, the same effect can be obtained when silver (Ag) is used as the second metal layer, not limiting to gold (Au).

The electrode pattern of the electrode 2 in a three layer structure can be obtained by depositing the first metal layer, the second metal layer and the third metal layer, on both whole surfaces of the quartz piece 10 by sputtering for instance, by forming a mask on both surfaces of the quartz piece 10 in a predetermined pattern, and by performing etching thereto.

According to the above-described embodiment, the electrode 2 formed on the surface of the plate quartz piece 10, the chromium (Cr) layer 23 is formed on the gold (Au) layer 22 and molecules of the one metal enter into molecules of the other metal, mixing with each other to form the so-called protective layer. Accordingly, gold (Au) atoms or chromium (Cr) atoms, metal atoms, get a state resistant to being scattered from the surface of the electrode 2 even at high temperatures of 300° C. and above for instance, and since metals excellent in adhesion to the quartz piece 10 such as chromium (Cr) or the like are used for the base plate, a quartz crystal resonator excellent in heat resistance and adhesion can be obtained.

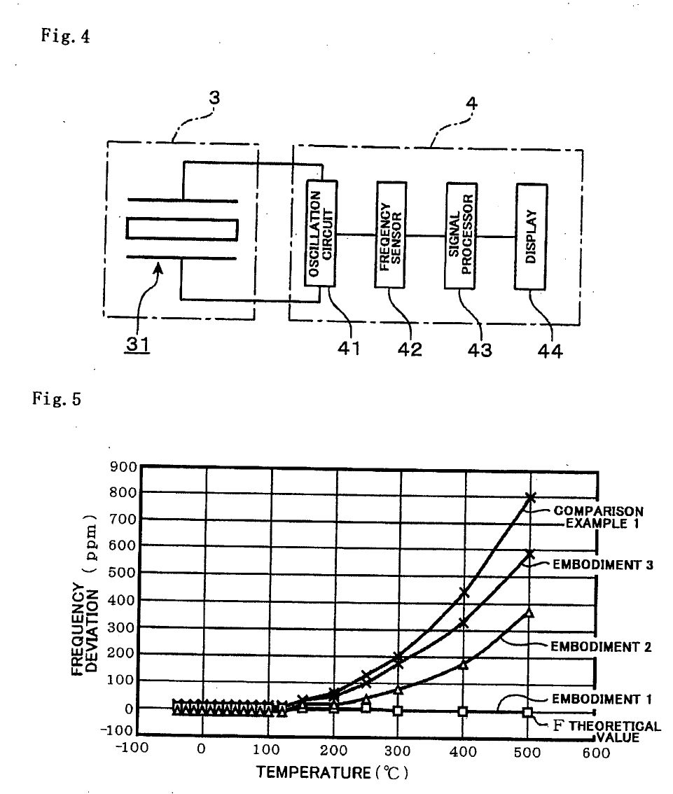

An example of temperature sensors using the above-described quartz crystal resonator will be explained with reference to FIG. 4. FIG. 4 is a block diagram showing an example of temperature sensors, in which 3 designates a detection unit, in which the above described quartz crystal resonator 31 is provided. 4 in FIG. 4 is a measurement unit, in which there are an oscillation circuit 41, a frequency sensor 42, a signal processor 43 and a display 44. The quartz resnonator 31 is connected to the oscillation circuit 41, and the frequency signal from the oscillation circuit 41 is measured by the frequency sensor 42. Based on the result of detection by the frequency sensor 42, the variation from the frequency sensor 42 in relation to a fiducial temperature is determined at the signal processor 43 so as to find a temperature corresponding to the variation and to display it in the display 44.

When the temperature sensor is made up using the above-described quartz crystal resonator 31 in this manner, it is possible to perform temperature measurement with high reliability even at high temperatures of 300° C. and above for instance, at which measurement has been conventionally difficult due to deterioration of the electrode 2. In other words, this kind of temperature sensor can be used as that having a measurable range including 300° C. or above, and is very useful as that substitutable for a slow-response thermocouple.

### Embodiment

Experiments conducted for confirming the effect of the present invention will be described next.

### Experiment 1

### A. Embodiment 1

In the quartz crystal resonator shown in FIG. 1, an AT cut quartz crystal having a fundamental vibration mode of 10.7 MHz was used for the quartz piece 10 and the thickness of the chromium (Cr) layer 21 being the first metal layer was set to 0.05 nm. Silver (Ag) was used for the second metal layer whose thickness was set to 0.15 nm, and the thickness of the chromium (Cr) layer 23 being the third metal layer was set to 0.1 nm. This formation is Embodiment 1.

### B. Embodiment 2

A quartz crystal resonator was made up in the same structure as in embodiment 1 except that the thickness of the chromium (Cr) layer 23 being the third metal layer was set to 0.01 mm. This formation is Embodiment 2.

### C. Embodiment 3

A quartz crystal resonator was made up in the same structure as in embodiment 1 except that the thickness of the chromium (Cr) layer 23 being the third metal layer was set to 0.005 nm. This formation is Embodiment 3.

### D. Embodiment 4

A quartz crystal resonator was made up in the same structure as in embodiment 1 except that gold (Au) was used for the second metal layer. This formation is Embodiment 4.

### E. Embodiment 5

A quartz crystal resonator was made up in the same structure as in embodiment 4 except that the thickness of the chromium (Cr) layer 23 being the third metal layer was set to 0.01 nm. This formation is Embodiment 5.

### F. Embodiment 6

A quartz crystal resonator was made up in the same structure as in embodiment 4 except that the thickness of the chromium (Cr) layer 23 being the third metal layer was set to 0.005 nm. This formation is Embodiment 6.

### G Comparison Example 1

A quartz crystal resonator was made up in the same structure as in embodiment 1 except that nothing was deposited on the surface of the silver (Ag) layer being the second metal layer.

### H. Comparison Example 2

A quartz crystal resonator was made up in the same structure as in Embodiment 4 except that nothing was deposited on the surface of the gold (Au) layer 22 being the second metal layer.

(Method of Experiment)

For the quartz crystal resonators in Embodiments 1 to 3 and Comparison Example 1, frequencies of the respective quartz crystal resonators in temperature range between −100° C. and 500° C. were measured. For the quartz crystal resonators in Embodiments 4 to 6 and Comparison Example 2, frequencies of the respective quartz crystal resonators at 500° C. were measured.

(Result and Consideration)

FIG. 5 shows the results of the frequency temperature characteristics of Embodiments 1 to 3 and Comparison Example 1, and the vertical axis designates the deviation (frequency deviation (ppm)) of the measurement value for the frequency of the quartz crystal resonator from its theoretical value corresponding to the temperature at that time. The horizontal axis designates temperatures (° C.). Note that F in FIG. 5 designates the theoretical value. As can be understood from FIG. 5, formation of chromium (Cr) on the surface of silver (Ag) at the second layer makes the frequency deviation from the theoretical value F small at a high temperature, and when focusing on the film thickness of chromium (Cr), it is understood that the frequency deviation from the theoretical value F becomes smaller in the order of Embodiment 3, Embodiment 2 and Embodiment 1. This means that when used at a high temperature, by arranging the film thickness of chromium (Cr) thicker, the frequency at each temperature comes close to its theoretical value so that temperatures can be sensed with high accuracy when it is used as a temperature sensor. The Comparison Example 1 is a quartz crystal resonator with no evaporation on the surface of silver (Ag) at the second layer. Accordingly, scattering of silver (Ag) atoms from the surface of the silver (Ag) layer cannot be reduced at high temperatures. This is the reason of extremely large frequency deviation from the theoretical value F.

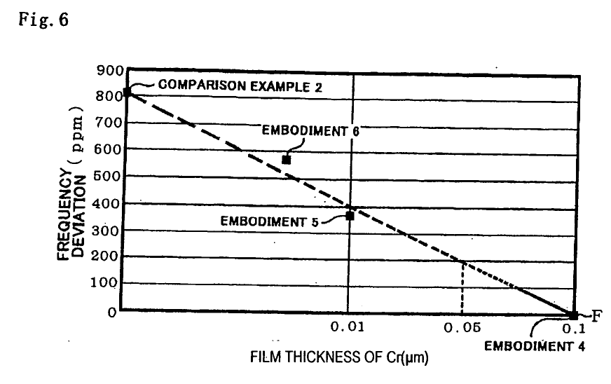

FIG. 6 shows the measurement result of frequencies in Embodiments 4 to 6 and in Comparison Example 2. As shown in FIG. 6, the vertical axis designates the frequency deviation (ppm) and the horizontal axis designates the film thickness (nm) of the chromium (Cr) formed on gold (Au) at the second layer. This frequency deviation is the deviation occurring between the measurement value and the theoretical value of the frequency at 500° C. In Embodiments 4 to 6 and in Comparison Example 2, when the film thicknesses of chromium (Cr) formed on the surface of gold (Au) at the second layer at 500° C. were plotted, a linear relation was obtained. From this result, it is understood that the oscillation frequency of the quartz crystal resonator at 500° C. becomes almost equal to its theoretical value F by setting the film thickness of chromium (Cr) formed on the surface of gold (Au) at the second layer to 0.1 nm. The present inventor expects that the temperature measurement can be performed with sufficient accuracy provided that the frequency is within about 200 ppm, and accordingly, the film thickness of chromium (Cr) layer 23 is preferably thicker than 0.05 nm. When the film thickness of chromium (Cr) layer 23 becomes thicker than 0.1 nm, increase in serial resistance occurs. Accordingly, it shows that if the film thickness of the chromium (Cr) layer 23 is within 0.05 nm to 0.1 nm, it is possible to perform temperature measurement with high accuracy provided that the temperature is within 500° C. or below.

1. A piezoelectric resonator provided with a electrode on the surface of the plate piezoelectric blank, which excites piezoelectric blank, wherein said electrode comprises:
a first metal layer, formed on the surface of the piezoelectric blank, and made of at least one kind selected from the group consisting of chromium (Cr), titanium (Ti), nickel (Ni), aluminum (Al) and copper (Cu), or having the same adhesion to said piezoelectric blank as that of these metals;
a second metal layer made of gold (Au) or silver (Ag) deposited on the surface of the first metal layer; and
a third metal layer made of chromium (Cr) deposited on the surface of the second metal layer.

2. The piezoelectric resonator according to claim 1, wherein the thickness of said third metal layer is 0.05 μm to 0.1 μm.

3. A temperature sensor, comprising a piezoelectric resonator and an oscillation circuit,
wherein said temperature sensor measuring temperatures by detecting the change in frequency oscillated from the oscillation circuit uses the piezoelectric resonator according to claim 1 or claim 2.

4. The temperature sensor according to claim 3, wherein temperature measurement range includes 300° C. or above.
